(19) United States
(12) Patent Application Publication
(10) Pub. No.: US 2026/0333740 A1
(43) Pub. Date: Oct. 22, 2026

(54) SEMICONDUCTOR DEVICES AND METHODS FOR MANUFACTURING

(71) Applicant: Taiwan Semiconductor Manufacturing Company, Ltd., Hsinchu (TW)

(72) Inventor: Ka-Hing Fung, Zhudong Township (TW)

(73) Assignee: Taiwan Semiconductor Manufacturing Company, Ltd., Hsinchu (TW)

(21) Appl. No.: 19/182,987

(22) Filed: Apr. 18, 2025

(51) Int. Cl. H10D 30/00; H01L 21/762; H01L 21/768; H10D 30/01; H10D 62/10; H10D 64/01; H10D 64/27

(52) U.S. Cl. CPC H10D 30/502; H10D 30/0191; H10D 64/01; H10D 64/512; H10W 10/014; H10W 10/17; H10W 20/056; H10W 20/089; H10D 62/121; H10D 64/519

(57) ABSTRACT

Semiconductor devices and methods for fabricating semiconductor devices are provided. A method includes forming a first channel region and a second channel region spaced apart from one another by a gap; forming a metal gate line over the first channel region, over the second channel region and in the gap; etching the metal gate line to define a first metal gate over the first channel region and a second metal gate over the second channel region, wherein the first metal gate and the second metal gate are disconnected; and forming a conductive bridge in contact with the first metal gate and in contact with the second metal gate.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart illustrating a method, in accordance with some embodiments.

FIG. 2 illustrates a top-down view of a semiconductor device, according to some embodiments.

FIGS. 3-5 are perspective views of a device during successive stages of fabrication of the method of FIG. 1, in accordance with some embodiments.

FIGS. 6-14 are cross-sectional views of a device during following stages of fabrication of the method of FIG. 1, in accordance with some embodiments.

### DETAILED DESCRIPTION

The following disclosure provides many different embodiments, or examples, for implementing different features of the subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “over”, “overlying”, “above”, “upper”, “top”, “under”, “underlying”, “beneath”, “below”, “lower”, “bottom”, “side”, and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In certain embodiments herein, a “material structure” is a structure that includes at least 50 wt. % of the identified material, for example at least 60 wt. % of the identified material, at least 75 wt. % of the identified material, at least 90 wt. % of the identified material, at least 95 wt. % of the identified material, or at least 99 wt. % of the identified material; and a structure that is formed of a “material” includes at least 50 wt. % of the identified material, for example at least 60 wt. % of the identified material, at least 75 wt. % of the identified material, at least 90 wt. % of the identified material, at least 95 wt. % of the identified material, or at least 99 wt. % of the identified material. For example, certain embodiments, each of a tungsten structure and a structure formed of tungsten is a structure that is at least 50 wt. %, at least 60 wt. %, at least 75 wt. %, at least 90 wt. %, at least 95 wt. %, or at least 99 wt. % of tungsten.

For the sake of brevity, typical techniques related to semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many typical processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

Presented herein are embodiments of semiconductor devices and of methods for fabricating such devices. Methods described herein may be easily integrated into the current process flow.

Embodiments described herein relate to the formation of an insulation structure, such as a cut metal gate dielectric structure, that divides a gate line, such as a metal gate line, into two distinct, i.e., disconnected, gate segments. In certain embodiments, a portion of the dielectric structure is then removed and replaced with conductive material. The conductive material forms a conductive bridge re-establishing electrical contact between the two distinct gate segments.

In certain embodiments, removal of conductive material and formation of the dielectric structure between the two gate segments provides for lower parasitic capacitance, particularly in a gate between an N region and a P region. Specifically, parasitic capacitance is reduced as compared to structures in which a thick metal gate continues, without reduction in height or width, in between an N region and a P region. Structures having a thick metal gate between N and P regions, may suffer from high parasitic capacitance.

Formation of the conductive bridge across or through the dielectric structure establishes conductivity between the re-connected gate segments between the N region and P region.

As a result of the described structure and reduced parasitic capacitance, certain embodiments may be provided with higher performance CMOS devices and higher logic density.

Certain embodiments herein describe a gate-all-around (GAA) semiconductor device; however, such description is not limiting. For example, embodiments herein may be utilized or result from fabrication processes for forming FinFET devices, GAA devices, advanced devices, industry semi-completed products or other devices or products.

Embodiments of the present disclosure offer advantages over the existing art, though it is understood that other embodiments may offer different advantages, not all advantages are necessarily discussed herein, and no particular advantage is required for all embodiments.

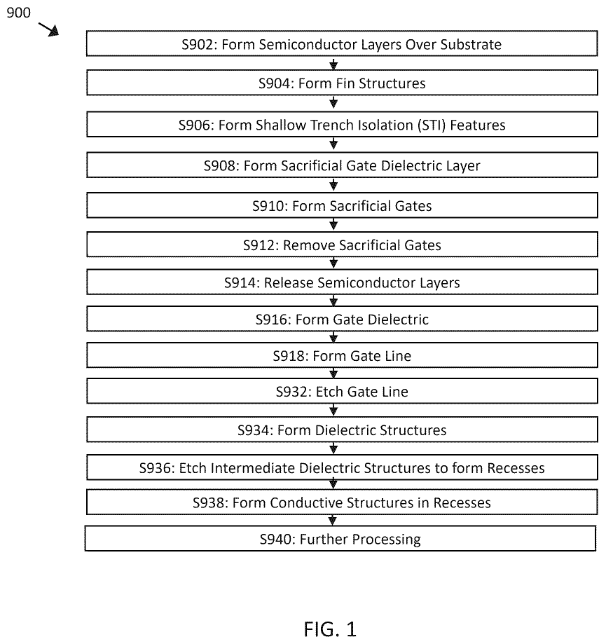

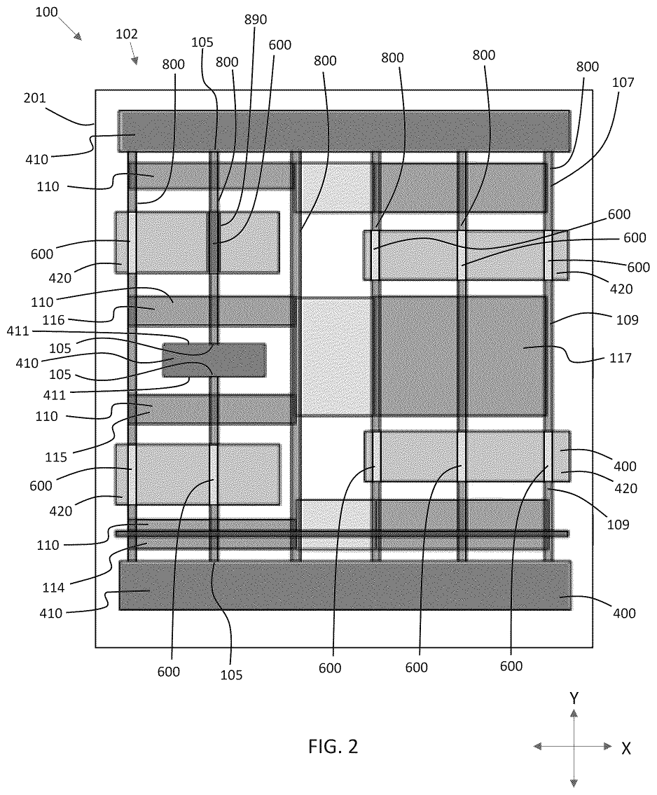

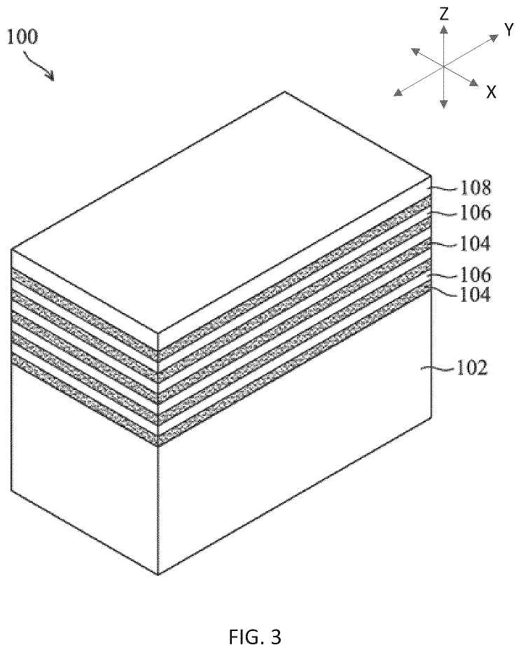

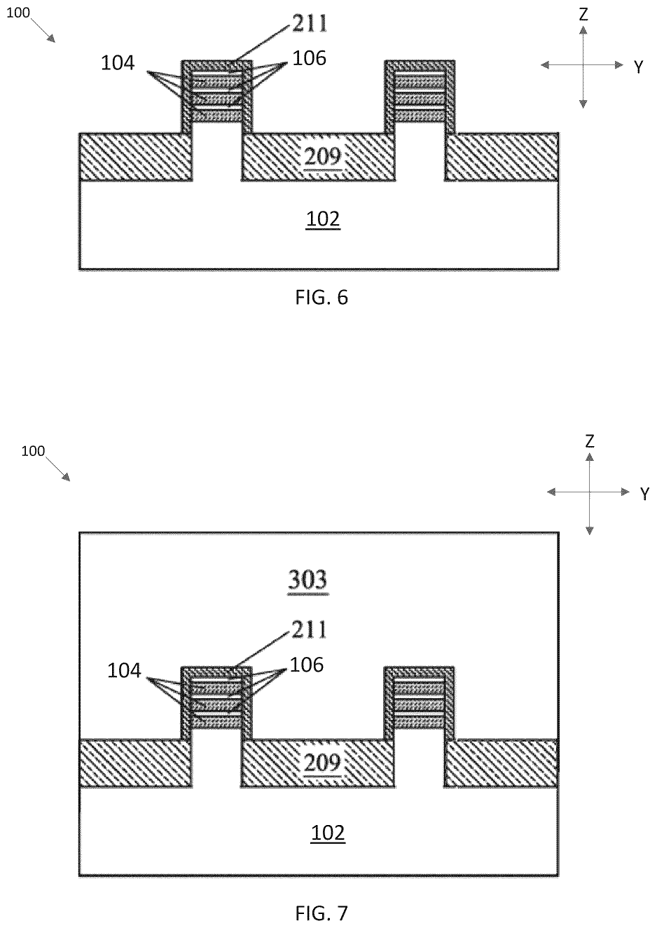

For purposes of the discussion that follows, FIG. 1 provides a flow chart for a method 900 for fabricating a semiconductor device 100 during a semiconductor fabrication process. Method 900 is described below with reference to FIGS. 3-14 which illustrate the semiconductor device 100 at various stages of fabrication according to method 900. FIGS. 3-5 are perspective views of the device 100 and FIGS. 6-14 are cross-sectional views in which the vertical direction is defined by the Z-axis and the lateral direction is defined by the Y-axis. FIG. 2 illustrates a top-down view of an intermediate structure in forming a semiconductor device 100 which may result from processing according to the method of FIG. 1.

In FIG. 2, the device 100 includes channel regions 110 formed from and/or over a portion 201 of a semiconductor substrate 102. In certain embodiments, the channel regions 110 may be fin structures and/or may be formed from a plurality of nanosheets over the substrate 102. As shown, the channel regions 110 may be parallel, extending in the X-direction and distanced from one another in the Y-direction. Channel regions 110 may maintain a constant width in the Y-direction. Alternatively, as shown, certain channel regions 110, such as channel region 114, may vary in width in the Y-direction. Further, certain channel regions 110 may merge, such as channel region 115 and 116, to form a wider merged channel region 117. Other layout options are possible, depending on the semiconductor device 100.

As shown in FIG. 2, gate segments or gates 800 are located over the channel regions 110. The gate segments 800 are formed by etching gate lines 107 formed over the channel regions 110. In certain embodiments, gate segments 800 are conductive and may be metal. As shown, gate lines 107 may be parallel, extending in the Y-direction and distanced from one another in the X-direction. Gate lines 107 may maintain a constant width in the X-direction. As shown, each gate line 107 may be formed with a same maximum length in the Y-direction.

As further shown in FIG. 2, the device 100 includes dielectric structures 400 formed across and interrupting selected gate lines 107 at selected locations to define lengths of gate segments 800. As shown, the dielectric structures 400 divide the gate lines 107 into two or more gate segments 800.

Dielectric structures 400 include terminal dielectric structures 410 and intermediate dielectric structures 420.

Terminal dielectric structures 410 completely interrupt gate lines 107 such that the gate segments 800 terminate at end surfaces 105 that are completely blocked by the end surfaces 411 of the respective terminal dielectric structures 410.

Intermediate dielectric structures 420 interrupt a portion, such as a lower portion, of the gate segments 800. Conductive paths between remaining portions of the gate segments 800 are formed by conductive structures 600, such as conductive bridges 600, that extend across or through the intermediate dielectric structures 420. Thus, a conductive path may be formed from a first gate segment interface with a first terminal dielectric structure 410, through the first gate segment, through the conductive bridge, through a second gate segment, to a second gate segment interface with a second terminal dielectric structure 410.

In certain embodiments, the terminal dielectric structures 410 and intermediate dielectric structures 420 are formed simultaneously by etching openings through the gate lines 107, and then forming dielectric structures 400 in the openings. Thereafter, the intermediate dielectric structures 420 are etched to form recesses in contact with and extending between opposite end surfaces 105 of the gate segments 800. Then, the conductive structures 600 are formed in the recesses, in contact with and extending between opposite end surfaces 105 of the gate segments 800.

As shown in FIG. 2, conductive gate plugs or contacts such as gate contact 890 or “conductive via over gate” 890 may be formed in contact with selected conductive structures 600. For example, conductive gate contact 890 is illustrated as lying over and in electrical contact with a conductive structure 600 interconnecting two gate segments 800.

Referring back to FIG. 1, method 900 may fabricate the semiconductor device 100 such as shown in FIG. 2. It is understood that method 900 includes steps having features of a complementary metal-oxide-semiconductor (CMOS) technology process flow and thus, are only described briefly herein. Also, additional steps may be performed before, after, and/or during method 900. In the illustrated embodiments, the semiconductor device structure 100 is a gate all around (GAA) transistor structure, and a cut metal gate process is provided.

The gate all around (GAA) transistor structures described may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Cross-referencing FIGS. 1 and 3, method 900 includes, at step S902, forming semiconductor layers 104 and 106 over a semiconductor substrate 102.

The substrate 102 may be made of silicon or other semiconductor materials. Alternatively or additionally, the substrate 102 may include other elementary semiconductor materials such as germanium. In some embodiments, the substrate 102 is made of a compound semiconductor such as silicon carbide, gallium arsenic, indium arsenide, or indium phosphide. In some embodiments, the substrate 102 is made of an alloy semiconductor such as silicon germanium, silicon germanium carbide, gallium arsenic phosphide, or gallium indium phosphide. In some embodiments, the substrate 102 includes an epitaxial layer. For example, the substrate 102 has an epitaxial layer overlying a bulk semiconductor.

A number of first semiconductor layers 104 and a number of second semiconductor layers 106 are sequentially alternately formed over the substrate 102. The semiconductor layers 104 and 106 are vertically stacked to form a stacked sheet structure.

In some embodiments, the first semiconductor layers 104 and the second semiconductor layers 106 independently include silicon (Si), germanium (Ge), silicon germanium (Si₁₋ₓGeₓ, 0.1<x<0.7, the value x is the atomic percentage of germanium (Ge) in the silicon germanium), indium arsenide (InAs), indium gallium arsenide (InGaAs), indium antimonide (InSb), or another applicable material. In some embodiments, the first semiconductor layer 104 and the second semiconductor layer 106 are made of different materials.

The first semiconductor layers 104 and the second semiconductor layers 106 are made of different materials having different lattice constant. In some embodiments, the first semiconductor layer 104 is made of silicon germanium (Si₁₋ₓGeₓ, 0.1<x<0.7), and the second semiconductor layer 106 is made of silicon (Si). In some other embodiments, the first semiconductor layer 104 is made of silicon germanium (Si₁₋ₓGeₓ, 0.1<x<0.7), and the second semiconductor layer 106 is made of germanium (Ge).

In some embodiments, the first semiconductor layers 104 and the second semiconductor layers 106 are formed by a selective epitaxial growth (SEG) process, a chemical vapor deposition (CVD) process (e.g. low-pressure CVD (LPCVD), plasma enhanced CVD (PECVD)), a molecular epitaxy process, or another applicable process. In some embodiments, the first semiconductor layers 104 and the second semiconductor layers 106 are formed in-situ in the same chamber.

In some embodiments, the thickness of each of the first semiconductor layers 104 is from 1.5 nanometers (nm) to 20 nm. In some embodiments, the first semiconductor layers 104 are substantially uniform in thickness. In some embodiments, the thickness of each of the second semiconductor layers 106 is from 1.5 nm to 20 nm. In some embodiments, the second semiconductor layers 106 are substantially uniform in thickness.

Next, a hard mask layer or layers 108 are formed over the first semiconductor layers 104. In some embodiments, each of the hard mask layers 108 is made of silicon nitride, silicon carbon nitride (SiCN), or applicable material. In some embodiments, the hard mask layers 108 are formed by a deposition process, such as low-pressure CVD (LPCVD) process, plasma enhanced CVD (PECVD) process, or another deposition process.

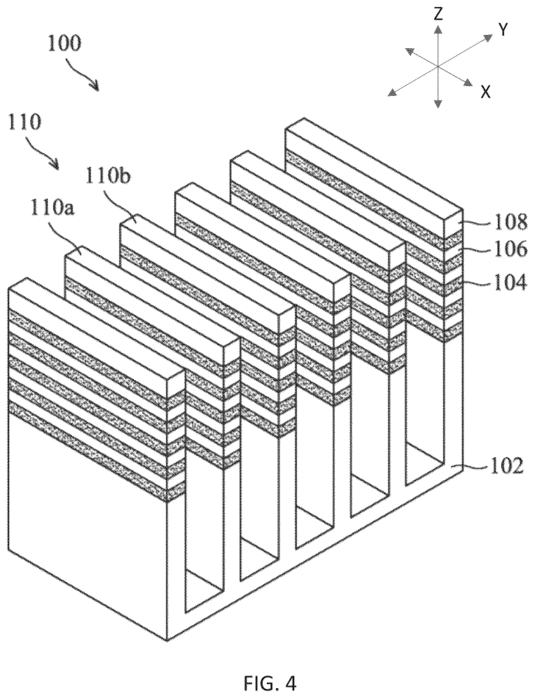

Cross-referencing FIGS. 1 and 4, method 900 includes, at step S904, forming fin structures 110, in accordance with some embodiments. As shown, the fin structures 110 include a first fin structure (or first stacked structure) 110a and a second fin structure (or second stacked structure) 110b.

The hard mask layer 108 may be patterned first. Then, the first semiconductor layers 104 and the second semiconductor layers 106 are patterned by using the patterned hard mask layer 108 as a mask. The fin structures 110 are formed by performing a patterning process on the first semiconductor layers 104 and the second semiconductor layers 106. The patterning process includes a photolithography process and an etching process. The photolithography process includes photoresist coating (e.g., spin-on coating), soft baking, mask aligning, exposure, post-exposure baking, developing the photoresist, rinsing and drying (e.g., hard baking). The etching process includes a dry etching process or a wet etching process.

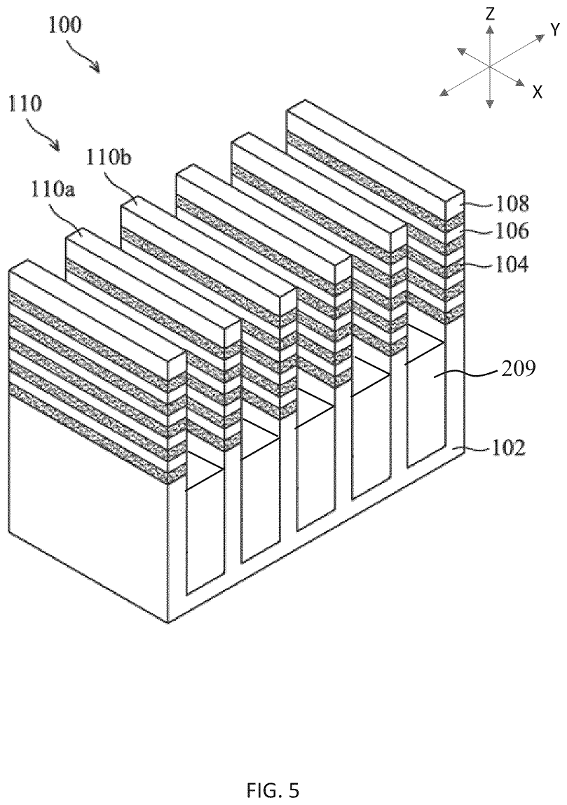

Cross-referencing FIGS. 1 and 5, method 900 includes, at step S906, forming an isolation feature or features 209 around the fin structures 110, in accordance with some embodiments. The isolation features 209 may be referred to as bottom isolation features 209.

In an exemplary embodiment, the isolation features 209 are formed as shallow trench isolation features by depositing a dielectric material in the trenches around the fin structures 110. According to some embodiments, the dielectric material used to form the isolation features 209 may be a material such as an oxide material (e.g., a flowable oxide), high-density plasma (HDP) oxide, or the like. The dielectric material may be formed, after an optional cleaning and lining of the trenches, using either a chemical vapor deposition (CVD) method (e.g., the HARP process), a high density plasma CVD method, or other suitable method of formation to fill or overfill the regions around the fin structures 110. In some embodiments, a post placement anneal process (e.g., oxide densification) is performed to densify the material of the isolation features 209 and to reduce its wet etch rate. A chemical mechanical polishing (CMP), an etch, a combination of these, or the like may be performed to remove any excess material of the isolation features 209.

After the dielectric material has been deposited to fill or overfill the regions around the fin structures 110, the dielectric material may then be recessed away from the surface of the fin structures 110 to form the isolation features 209. The recessing may be performed to expose at least a portion of the sidewalls of the fin structures 110 adjacent to the top surface of the fin structures 110. The dielectric material may be recessed using a wet etch by dipping the top surface of the fin structures 110 into an etchant selective to the material of the dielectric material, although other methods, such as a reactive ion etch, a dry etch, chemical oxide removal, or dry chemical clean may be used.

FIG. 6 is a cross-sectional view of the device 100 of FIG. 5 at a successive fabrication stage. It is noted that FIGS. 3-5 illustrate five first semiconductor layers 104 and four second semiconductor layers 106, with the hard mask layer 108 being formed on the topmost first semiconductor layer 104. Embodiments herein are not so limited, and FIGS. 6-14 illustrate embodiments which include three first semiconductor layer 104 and three second semiconductor layers 106, with the topmost second semiconductor layer 106 forming the top of the stack 100.

Cross-referencing FIGS. 1 and 6, method 900 includes, at step S908, forming a dummy gate dielectric 211 over the exposed portions of the fin structures 110. After the isolation features 209 have been formed, the dummy gate dielectric 211 may be formed by thermal oxidation, chemical vapor deposition, sputtering, or any other methods known and used in the art for forming a gate dielectric. Depending on the technique of gate dielectric formation, the dummy gate dielectric 211 thickness on the top may be different from the dummy dielectric thickness on the sidewall. In some embodiments, the dummy gate dielectric 211 may be formed by depositing a material such as silicon and then oxidizing or nitridizing the silicon layer in order to form a dielectric such as the silicon dioxide or silicon oxynitride. In other embodiments, the dummy gate dielectric 211 may also be formed from a high permittivity (high-k) material such as lanthanum oxide (La₂O₃), aluminum oxide (Al₂O₃), hafnium oxide (HfO₂), hafnium oxynitride (HfON), or zirconium oxide (ZrO₂), or combinations thereof. Additionally, any combination of silicon dioxide, silicon oxynitride, and/or high-k materials may also be used for the dummy gate dielectric 211.

Cross-referencing FIGS. 1 and 7, method 900 may continue, at S910, with forming sacrificial or dummy gate 303 over the fin structures 110, in accordance with some embodiments. Specifically, the sacrificial gate 303 is formed over the dummy gate dielectric 211.

In some embodiments, the dummy gate electrode 303 comprises a conductive material and may be selected from a group comprising of polysilicon, W, Al, Cu, AlCu, W, Ti, TiAlN, TaC, TaCN, TaSiN, Mn, Zr, TiN, Ta, TaN, Co, Ni, combinations of these, or the like. The dummy gate electrode 303 may be deposited by chemical vapor deposition (CVD), sputter deposition, or other techniques known and used in the art for depositing conductive materials. The top surface of the dummy gate electrode 303 may have a non-planar top surface, and may be planarized prior to patterning of the dummy gate electrode 303 or gate etch. Ions may or may not be introduced into the dummy gate electrode 303 at this point. Ions may be introduced, for example, by ion implantation techniques.

After the dummy gate electrode 303 has been formed, the dummy gate dielectric 211 and the dummy gate electrode 303 may be patterned. In an embodiment the patterning may be performed by initially forming a hard mask or masks over the dummy gate electrode 303. The masks are then patterned. Thereafter, various processes may be performed to form desired structures, etching of the dummy gate material to form distinct dummy gate stacks, formation of spacers, etching of openings for source/drain regions, epitaxial growth of source/drain regions, implant processes, and other typical gate processing. The hard masks may then be removed. According to some embodiments, one or more etching processes and/or the chemical mechanical planarization (CMP) may be utilized to remove the hard masks. As such, the dummy gate electrode 303 is exposed after the removal of the hard masks.

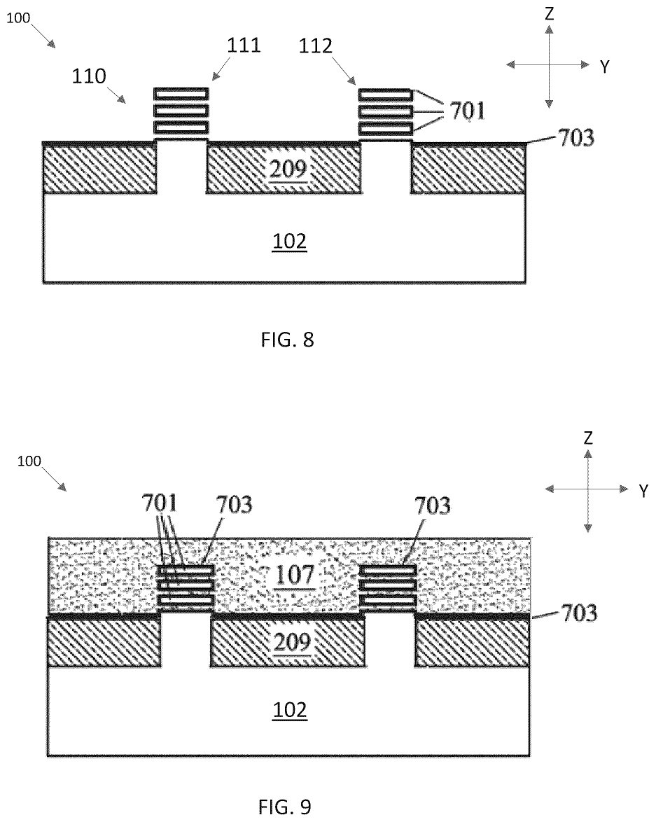

Cross-referencing FIGS. 1 and 8, method 900 may continue, at step S912, with removing the dummy gate electrode 303 and the dummy gate dielectric 211.

Still cross-referencing FIGS. 1 and 8, method 900 may continue, at step S914, with performing a sheet-release process to remove semiconductor layers 104 and to form nanostructures 701, i.e., vertically-spaced nanosheets, from the semiconductor layers 106, in accordance with some embodiments.

As shown, the nanosheets 701 define channel regions 110. Specifically, a first channel region 111 and a second channel region 112 are defined, each including a set of vertically-spaced nanosheets 701.

Still cross-referencing FIGS. 1 and 8, method 900 may continue, at step S916, with forming a gate dielectric 703 over the nanostructures 701, according to some embodiments.

After being exposed by removal of the hard masks, the dummy gate electrode 303 may be removed in order to expose the underlying dummy gate dielectric 211. In an embodiment the dummy gate electrode 303 is removed using, e.g., one or more wet or dry etching process that utilizes etchants that are selective to the material of the dummy gate electrode 303. However, any suitable removal process may be utilized.

After the dummy gate dielectric 211 has been exposed by removal of the dummy gate electrode 303, the dummy gate dielectric 211 may be removed. In an embodiment the dummy gate dielectric 211 may be removed using, e.g., a wet etching process, although any suitable etching process may be utilized.

After the dummy gate dielectric 211 has been removed (which also exposes the sides of the semiconductor layers 104), the semiconductor layers 104 may be removed from between the substrate 102 and from between the semiconductor layers 106 in a sheet release process step. The sheet release process step may also be referred to as a wire release process step, a sheet formation process step, a nanosheet formation process step or a sheet formation process step. In an embodiment the semiconductor layers 104 may be removed using a wet etching process that selectively removes the material of the semiconductor layers 104 (e.g., silicon germanium (SiGe)) without significantly removing the material of the substrate 102 and the material of the semiconductor layers 106 (e.g., silicon (Si)). However, any suitable removal process may be utilized.

For example, in an embodiment, an etchant such as a high temperature HCl may be used to selectively remove the material of the semiconductor layers 104 (e.g., SiGe) without substantively removing the material of the substrate 102 and/or the material of the semiconductor layers 106 (e.g., Si). Additionally, the wet etching process may be performed at a temperature of from 400 °C to about 600 °C, such as about 560 °C, and for a time of from about 100 seconds to about 600 seconds, such as about 300 seconds. However, any suitable etchant, process parameters, and time can be utilized.

FIG. 8 further illustrates the formation of the gate dielectric 703 over the nanostructures 701, according to some embodiments. In an embodiment the gate dielectric 703 comprises a high-k material (e.g., K greater than or equal to 9) such as Ta₂O₅, Al₂O₃, Hf oxides, Ta oxides, Ti oxides, Zr oxides, Al oxides, La oxides (e.g., HfO₂, HfSiO, HfSiON, HfTaO, HfTiO, HfZrO, LaO, ZrO, TiO), combinations of these, or the like, deposited through a process such as atomic layer deposition, chemical vapor deposition, or the like. In some embodiments, the gate dielectric 703 comprises a nitrogen doped oxide dielectric that is initially formed prior to forming a metal content high-K (e.g., K value>13) dielectric material. The gate dielectric 703 may be deposited to a thickness of from about 1 nm to about 3 nm, although any suitable material and thickness may be utilized. In exemplary embodiments, the gate dielectric 703 wraps around the nanostructures 701, thus forming channel regions.

Cross-referencing FIGS. 1 and 9, method 900 may continue, at step S918, with forming a gate line 107 over the channel regions 110. For example, method 900 includes forming a gate line 107, in accordance with some embodiments. After the gate dielectric 703 has been formed, the gate lines 107 are formed to surround the nanostructures 701. As shown, inter-sheet portions of the metal gate are located between the nanosheets 701.

In some embodiments, the gate lines 107 are formed using multiple layers, each layer deposited sequentially adjacent to each other using a highly conformal deposition process such as atomic layer deposition, although any suitable deposition process may be utilized. According to some embodiments, the gate lines 107 may comprise a capping layer, a barrier layer, an n-metal work function layer, a p-metal work function layer, and a fill material.

The capping layer may be formed adjacent to the gate dielectric 703 and may be formed from a metallic material such as TaN, Ti, TiAlN, TiAl, Pt, TaC, TaCN, TaSiN, Mn, Zr, TiN, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The metallic material may be deposited using a deposition process such as atomic layer deposition, chemical vapor deposition, or the like, although any suitable deposition process may be used.

The barrier layer may be formed adjacent the capping layer, and may be formed of a material different from the capping layer. For example, the barrier layer may be formed of a material such as one or more layers of a metallic material such as TiN, TaN, Ti, TiAlN, TiAl, Pt, TaC, TaCN, TaSiN, Mn, Zr, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The barrier layer may be deposited using a deposition process such as atomic layer deposition, chemical vapor deposition, or the like, although any suitable deposition process may be used.

The n-metal work function layer may be formed adjacent to the barrier layer. In an embodiment the n-metal work function layer is a material such as W, Cu, AlCu, TiAlC, TiAlN, TiAl, Pt, Ti, TiN, Ta, TaN, Co, Ni, Ag, Al, TaAl, TaAlC, TaC, TaCN, TaSiN, Mn, Zr, other suitable n-type work function materials, or combinations thereof. For example, the first n-metal work function layer may be deposited utilizing an atomic layer deposition (ALD) process, CVD process, or the like. However, any suitable materials and processes may be utilized to form the n-metal work function layer.

The p-metal work function layer may be formed adjacent to the n-metal work function layer. In an embodiment, the first p-metal work function layer may be formed from a metallic material such as W, Al, Cu, TiN, Ti, TiAlN, TiAl, Pt, Ta, TaN, Co, Ni, TaC, TaCN, TaSiN, TaSi₂, NiSi₂, Mn, Zr, ZrSi₂, TaN, Ru, AlCu, Mo, MoSi₂, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. Additionally, the p-metal work function layer may be deposited using a deposition process such as atomic layer deposition, chemical vapor deposition, or the like, although any suitable deposition process may be used.

After the p-metal work function layer has been formed, the fill material is deposited to fill a remainder of the opening. In an embodiment the fill material may be a material such as tungsten, Al, Cu, AlCu, W, Ti, TiAlN, TiAl, Pt, TaC, TaCN, TaSiN, Mn, Zr, TiN, Ta, TaN, Co, Ni, combinations of these, or the like, and may be formed using a deposition process such as plating, chemical vapor deposition, atomic layer deposition, physical vapor deposition, combinations of these, or the like. However, any suitable material may be utilized.

After the openings left behind by the removal of the dummy gate electrode 303 have been filled, the materials of the gate line 107 and the gate dielectric 703 may be planarized in order to remove any material that is outside of the openings left behind by the removal of the dummy gate electrode 303. In a particular embodiment the removal may be performed using a planarization process such as chemical mechanical polishing, although any suitable planarization and removal process may be utilized. According to some embodiments, the gate electrodes may be formed to a length of from about 8 nm to about 30 nm. However, any suitable length may be used.

After being formed, the gate lines 107 may be recessed. According to some embodiments, the gate lines 107 may be recessed using an etching process such as a wet etch, a dry etch, combinations, or the like.

Gate caps may be formed over the gate lines 107 by initially depositing a dielectric material over the gate lines 107 to fill and/or overfill the recesses. In some embodiments, the gate caps are formed using a dielectric material such as a silicon nitride (SiN), oxide (OX), silicon oxynitride (SiON), silicon oxycarbonitride (SiOCN), silicon carbonitride (SiCN), or the like. According to some embodiments, the gate caps are formed using a metal oxide of materials such as zirconium (Zr), hafnium (Hf), aluminum (Al), or the like. Furthermore, the gate caps may be formed using a suitable deposition process such as chemical vapor deposition (CVD), atomic layer deposition (ALD), physical vapor deposition (PVD), combinations of these, or the like. However, any suitable materials and deposition processes may be utilized. After being deposited, the gate caps may be planarized using a planarization process such as a chemical mechanical polishing process.

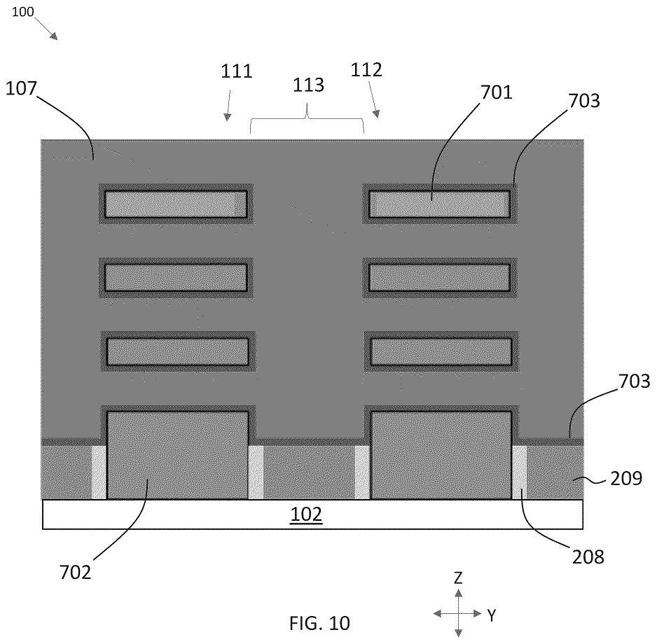

FIG. 10 illustrates an embodiment of the device 100 after forming the gate line 107. As shown, each channel region 111 and 112 includes vertically-spaced nanosheets 701 and a bottom channel region 702 which may be formed from a portion of the substrate 102. The bottom channel regions 702 may be referred to as mesas or mesa portions. A bottom isolation feature 209 is located between adjacent bottom channel regions 702.

As shown, the first channel region 111 and second channel region 112 are spaced apart from one another by a gap 113. Step S918 includes forming the gate line 107 over the first channel region 111, over the second channel region 112 and in the gap 113.

Further, FIG. 10 illustrates that an additional dielectric liner 208 may located between the STI features 209 and the bottom channel regions 702.

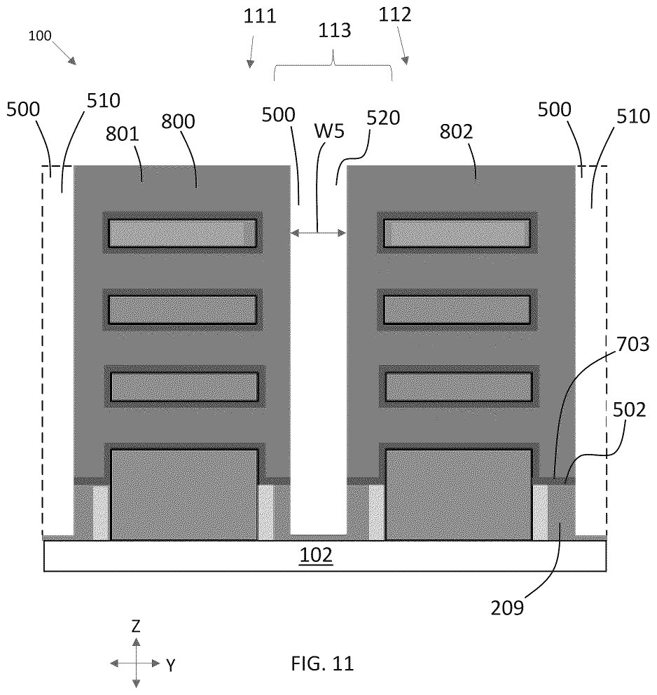

Cross-referencing FIGS. 1 and 11, method 900 may continue, at step S932, with etching the gate line 107 to define gates or gate segments 800. For example, step S932 etches the gate line 107 to form a first gate segment 801 over the first channel region 111 and a second gate segment 802 over the second channel region 112. As shown, the gate segments 801 and 802 are distinct and disconnected from one another after etching the gate line 107.

As shown, openings 500 are formed by etching the gate line 107. The openings 500 include terminal openings 510 and intermediate openings 520. As shown, the openings 500 extend vertically through the gate line 107, through the gate dielectric 703, and into the bottom isolation features 209. In other words, the process for etching the gate line 107 may include etching the gate dielectric 703 and etching the bottom isolation features 209. In certain embodiments, the openings 500 may extend through the bottom isolation features 209 to contact or extend into the substrate 102.

As shown, the terminal openings 500 may have a lateral width W5, in the Y-direction. In certain embodiments, width W5 of the openings 500 may be from 4 to 25 nanometers. For example, width W5 may be at least 4 nm, such as at least 5 nm, at least 6 nm, at least 8 nm, at least 10 nm, at least 12 nm, at least 15 nm, or at least 20 nm. Further, width W5 may be at most 25 nm, such as at most 20 nm, at most 18 nm, at most 15 nm, at most 12 nm, at most 10 nm, or at most 8 nm.

In certain embodiments, step S932 may include or be a cut-gate process. After the gate caps have been planarized, a masking layer may be deposited over the planar surfaces of the gate caps. After being deposited, the masking layer is patterned to expose the underlying materials including the gate caps in desired locations of the cut-gate dielectric structures that are to be formed.

After being patterned, the masking layer is used as an etching mask to etch the underlying materials to form the openings 500 (e.g., trenches, recesses, channels or the like). In the etching process, the materials of the gate caps and the gate lines 107 are etched using an anisotropic etching process. In exemplary embodiments, the etch process continues through the gate dielectric 703 and into the isolation features 209. The openings 500 may be formed between adjacent channel regions 110 and may be formed to cut through one or more gate lines 107. After the openings 500 have been formed, the masking layer is removed.

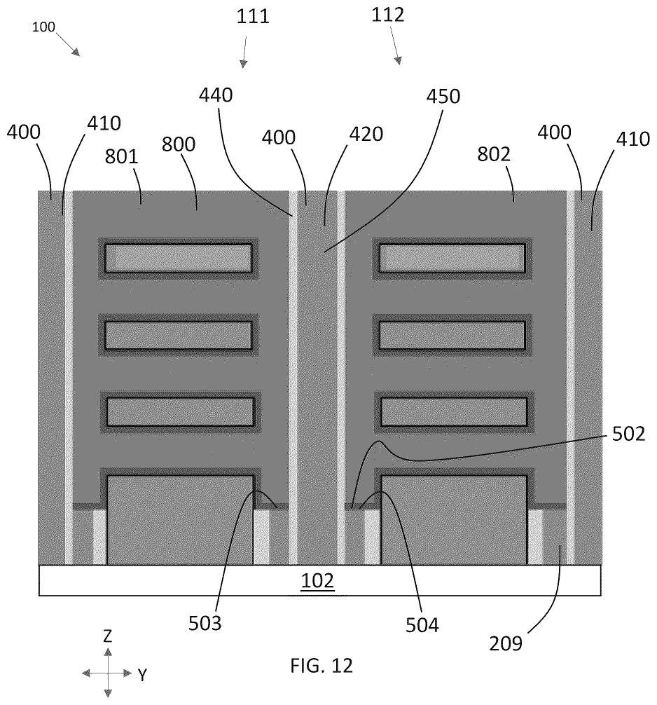

Cross-referencing FIGS. 1 and 12, method 900 may continue, at step S934, with forming dielectric structures 400 in the openings 500. In certain embodiments, the dielectric structures 400 are formed in a cut-gate process and may be referred to as gate isolation or isolation structures 400. After the openings 500 have been formed, the dielectric structures 400 are formed by initially lining the openings 500 with a dielectric liner 440 and then depositing a dielectric material fill 450 to fill and overfill the openings 500. Thereafter, a planarization process may be performed to remove portions of the dielectric liner 440 and dielectric material fill 450 lying over the gate segments 800.

In accordance with some embodiments, the dielectric structures 400 are formed using any suitable dielectric materials and suitable deposition process. The dielectric liner 440 and dielectric fill material 450 may be the same or different materials. The dielectric liner 440 and/or dielectric fill material 450 may be formed using silicon nitride, silicon oxide, silicon oxynitride, or other suitable dielectric material.

The dielectric structures 400 divide the gate lines 107, which are relatively long, into a plurality of gate segments 800 which are relatively short and isolate the gate segments 800 from one another.

In certain embodiments, the dielectric structures 400 are formed in contact with the bottom isolation features 209.

In FIG. 12, dielectric structures 400 formed in terminal openings 510 are terminal dielectric structures 410 and dielectric structures 400 formed in intermediate openings 520 are intermediate dielectric structures 420. In certain embodiments, terminal dielectric structures 410 and intermediate dielectric structures 420 are formed simultaneously, i.e., during a same process.

As shown, the dielectric structures 400, including the terminal dielectric structures 410 and the intermediate dielectric structures 420, at least partially extend into the bottom isolation feature 209. Further, each of the dielectric liner 440 and dielectric fill material 450 at least partially extends into the bottom isolation feature 209.

In FIG. 12, the intermediate dielectric structure 420 is located in the gap 113 (FIG. 10) between the first channel region 111 and second channel region 112. Terminal dielectric structures 410 may be located adjacent to terminal channel regions 110 or between channel regions 110 depending on the layout of the device 100.

After later processing described below, terminal dielectric structures 410 may terminate electrical or conductive pathways, as no conductive paths are formed across the terminal dielectric structures 410, while later processing may form conductive paths across the intermediate dielectric structures 420 such that intermediate dielectric structures 420 do not terminate electrical or conductive pathways.

In certain embodiments, step S934, or steps S932 and S934 collectively, may include interrupting designated gate lines 107 with dielectric structures 400. Interrupting designated gate lines 107 with dielectric structures 400 may include contacting the bottom isolation features 209 with the dielectric structures 400.

As further shown in FIG. 12, the bottom isolation feature 209 has an uppermost surface 502. As shown, gate segment 801 contacts a first portion 503 of the uppermost surface 502 and gate segment 802 contacts a second portion 504 of the uppermost surface 502. As shown, the intermediate dielectric structure 420 contacts the bottom isolation feature 209 between the first portion 503 and the second portion 504 of the uppermost surface 502 of the bottom isolation feature 209.

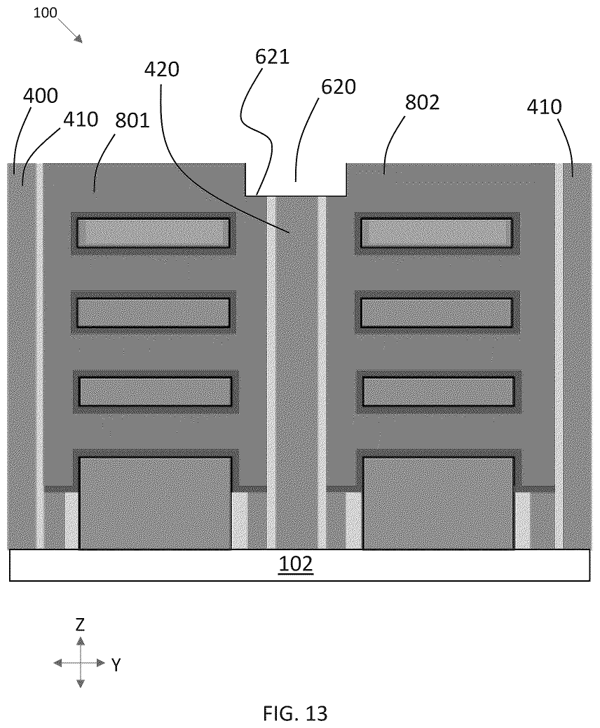

As shown in FIG. 1, method 900 may continue, at step S936, with etching intermediate dielectric structures 420 to form recesses 620. For example, as shown in FIG. 13, a recess 620 is formed by etching the intermediate dielectric structure 420. As shown, the etching process may etch the first gate segment 801, the second gate segment 802, and the intermediate dielectric structure 420. Specifically, the etching process etches a portion of the first gate segment 801, a portion of the second gate segment 802, and a portion of the intermediate dielectric structure 420. As a result, the recess 620 is formed with a recess bottom surface 621 that is formed by the first gate segment 801, the intermediate dielectric structure 420, and the second gate segment 802.

Step S936 may include a patterning process including a photolithography process and an etching process. The photolithography process includes photoresist coating (e.g., spin-on coating), soft baking, mask aligning, exposure, post-exposure baking, developing the photoresist, rinsing and drying (e.g., hard baking). The etching process includes a dry etching process or a wet etching process.

After lithography processing, exposed underlying materials are etched to form the recesses 620 (e.g., trenches, openings, channels or the like). In the etching process, the materials of the intermediate dielectric structures 420 and adjacent portions of gate segments 800 are etched using an anisotropic etching process. After the recesses 620 have been formed, the masks and/or photoresist is removed.

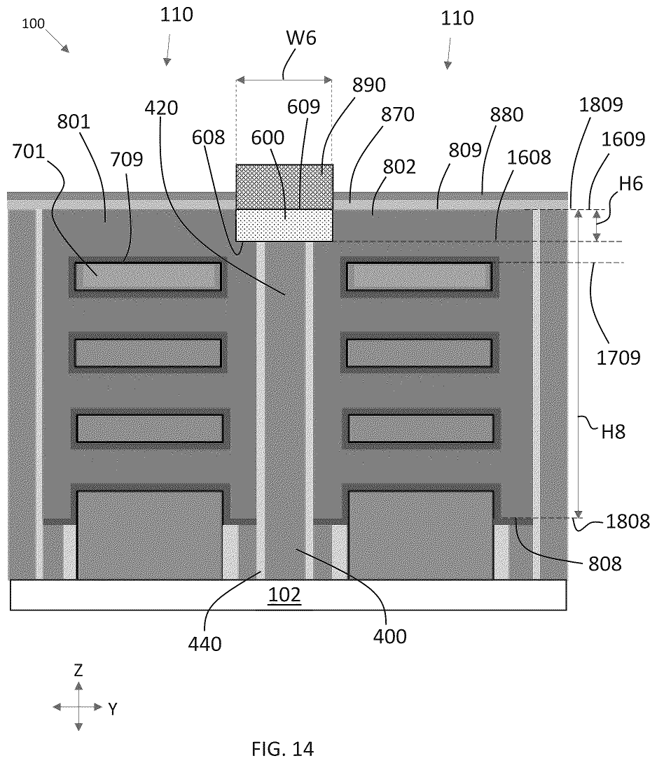

Cross-referencing FIGS. 1 and 14, method 900 may continue, at step S938, with forming conductive structures 600 in the recesses 620. For example, conductive material is deposited on the surfaces 621 of the recesses 620, and the recesses 620 are filled with the conductive material. In certain embodiments, the conductive material is a metal, such as tungsten, though copper, aluminum, or other metal or conductive material may be used. The deposition process may result in an overburden portion of the conductive material being located over the upper surfaces of the gate segments 801 and 802. After depositing the conductive material of structures 600, the excess conductive material outside of the recesses 620 may be removed by a chemical mechanical planarization (CMP) process.

Conductive structure 600 contacts the gate segment 801 at uppermost surface 809 and contacts gate segment 802 at uppermost surface 809.

Step S938, or steps S936 and S938 includes electrically reconnecting selected gates lines 107 across selected dielectric structures 420.

As shown, the conductive structures 600 bridge the intermediate dielectric structures 420 and physically contact the first gate segments 801 and the second gate segments 802. Thus, the conductive structures 600 conductively contact the first gate segments 801 and the second gate segments 802. The conductive structures 600 may be referred to as conductive bridges 600.

As shown, the conductive structure 600 has a lateral width W6 while intermediate dielectric structure 400 has lateral width W5 (shown in FIG. 11). Width W6 is greater than width W5.

As shown in FIG. 14, the conductive structure 600 has a bottommost surface 608 and an uppermost surface 609. Bottommost surface 608 defines a bottommost bridge plane 1608, and uppermost surface 609 defines an uppermost bridge plane 1609. Planes 1608 and 1609 may be parallel. As shown in FIG. 14, the conductive structure 600 has a maximum vertical thickness or height H6, in the Z-direction, defined as the vertical distance between planes 1608 and 1609.

As further shown, in each channel region 110, an uppermost channel surface 709 is defined by an uppermost nanosheet 701. The uppermost channel surfaces 709 may define an uppermost channel plane 1709. As shown in FIG. 14, the uppermost channel plane 1709 is located between the bottommost plane 1608 and the substrate 102. In other words, the conductive structure 600 is not formed as deeply into the gate segments 801/802 as the respective uppermost nanosheet channels 701 are.

The conductive structure 600 may be formed from a suitable conductive material, such as a metal. In certain embodiments, the conductive structure 600 is or includes tungsten.

In embodiments in which the conductive structure 600 and the gate segments 801/802 are formed from the same material, an interface may not be formed between the conductive structure 600 and the gate segments 801/802. As the conductive structure 600 is formed from a material different from the dielectric structure 400 and dielectric liner 440, an interface is formed between the conductive structure 600 and the dielectric structure and liner 400/440.

In FIG. 14, each gate segment 801/802 has a bottommost surface 808. The bottommost surfaces 808 define a bottommost gate plane 1808. Further, each gate segment 801/802 has an uppermost surface 809. The uppermost surfaces 809 define an uppermost gate plane 1809. In certain embodiments, uppermost gate plane 1809 and uppermost bridge plane 1609 are co-planar, i.e., the same plane.

As shown in FIG. 14, each gate segment 801/802 has a maximum vertical thickness or height H8, in the Z-direction, defined as the vertical distance between planes 1808 and 1809. Each gate segment 801/802 extends upward from the bottom isolation feature 209 and terminates at uppermost surface 809.

In certain embodiments, the ratio of bridge height H6 to gate height H8 (H6/H8) is at least 0.05, such as at least 0.06, at least 0.08, at least 0.1, at least 0.12, at least 0.15, at least 0.2, at least 0.25, at least 0.3, at least 0.35, at least 0.4, at least 0.45, at least 0.5, at least 0.55, at least 0.6, at least 0.65, at least 0.7, or at least 0.75. In certain embodiments, the ratio of bridge height H6 to gate height H8 (H6/H8) is at most 0.8, such as at most 0.75, at most 0.7, at most 0.65, at most 0.6, at most 0.55, at most 0.5, at most 0.45, at most 0.4, at most 0.35, at most 0.3, at most 0.25, at most 0.2, at most 0.15, at most 0.12, at most 0.1, at most 0.08, at most 0.06, or at most 0.05.

The ratio of H6/H8 may be selected to provide a desired reduced parasitic capacitance. For example, bridge height H6 may be selected to cooperate with a given gate height H8 to provide the desired reduced parasitic capacitance.

Cross-referencing FIGS. 2 and 14, selected gate lines 107 terminates at a first terminal dielectric structure 410 and at a second terminal dielectric structure 410, and a conductive path of the gate line 107 extends from the first terminal dielectric structure 410 to the second terminal dielectric structure 410 over a first channel region 111, over a second channel region 112, and through intermediate dielectric structure 420 located between the first channel region 111 and the second channel region 112.

As shown in FIG. 1, method 900 may continue, at S940, with further processing for completing the device 100. For example, the further processing may include forming interlayer dielectric and metallization layers, forming contacts, and forming conductive vias, in accordance with some embodiments.

As shown in FIG. 14, S940 may include forming a dielectric liner 870 over the uppermost surfaces 809 of gate segments 801/802. The dielectric liner 870 may be formed using silicon nitride, silicon oxide, silicon oxynitride, or other suitable dielectric material.

As shown in FIG. 14, S940 may include forming a dielectric structure 880 over the dielectric liner 870. The dielectric structure 880 may be formed using silicon nitride, silicon oxide, silicon oxynitride, or other suitable dielectric material.

As further shown in FIG. 14, a conductive gate plug or contact 890 may be formed in contact with selected conductive structures 600. For example, the dielectric liner 870 and dielectric structure 880 may be etched over the selected conductive structure 600 to uncover the selected conductive structure 600, and a metal fill may be deposited and planarized to form the conductive gate contact 890. Alternatively, the conductive gate contact 890 may be formed before the dielectric liner 870 and dielectric structure 880.

While the conductive gate contact 890 is illustrated as only being in electrical contact with the conductive structure 600, it is contemplated the conductive gate contact 890 also be in direct electrical contact with a portion of the first gate segment 801 and/or a portion of the second gate segment 802.

In one embodiment, a method is provided for forming a semiconductor substrate. The method includes forming a first channel region and a second channel region spaced apart from one another by a gap; forming a metal gate line over the first channel region, over the second channel region and in the gap; etching the metal gate line to define a first metal gate over the first channel region and a second metal gate over the second channel region, wherein the first metal gate and the second metal gate are disconnected; and forming a conductive bridge in contact with the first metal gate and in contact with the second metal gate.

In certain embodiments of the method, the first channel region includes first vertically-spaced nanosheets; and the second channel region includes second vertically-spaced nanosheets.

In certain embodiments, the method includes forming an intermediate dielectric structure between the first metal gate and the second metal gate.

In certain embodiments, the method includes etching the intermediate dielectric structure to form a recess, wherein the conductive bridge is formed in the recess.

In certain embodiments, the method includes forming a bottom isolation feature located between the first channel region and the second channel region, wherein forming the intermediate dielectric structure between the first metal gate and the second metal gate includes forming the intermediate dielectric structure in contact with the bottom isolation feature.

In certain embodiments of the method, the first channel region and the second channel region are formed over a semiconductor substrate; the first channel region and the second channel region each include an uppermost channel surface; the uppermost channel surfaces define an uppermost channel plane; and the uppermost channel plane is located between the conductive bridge and the semiconductor substrate.

In certain embodiments of the method, etching the metal gate line to define a first metal gate over the first channel region and a second metal gate over the second channel region includes forming an intermediate opening in the gap between the first channel region and the second channel region; forming a first terminal opening adjacent the first channel region, wherein the first channel region is located between the first terminal opening and the intermediate opening; and forming a second terminal opening adjacent the second channel region, wherein the second channel region is located between the second terminal opening and the intermediate opening.

In certain embodiments, the method includes forming an intermediate dielectric structure in the intermediate opening; forming a first terminal dielectric structure in the first terminal opening; forming a second terminal dielectric structure in the second terminal opening; and etching the intermediate dielectric structure to form a recess, wherein the conductive bridge is formed in the recess.

In another embodiment, a method includes forming channel regions over a semiconductor substrate, wherein the channel regions extend in a first direction; forming gate lines over the channel regions, wherein the gate lines extend in a second direction transverse to the first direction; interrupting designated gate lines with dielectric structures; and electrically reconnecting selected gates lines across selected dielectric structures.

In certain embodiments of the method, electrically reconnecting selected gates lines across selected dielectric structures includes etching the selected dielectric structures to form recesses; and forming conductive bridges in the recess.

In certain embodiments of the method, a first selected gate line terminates at a first non-selected dielectric structure and at a second non-selected dielectric structure; and a conductive path of the first selected gate line extends from the first non-selected dielectric structure to the second non-selected dielectric structure over a first channel region, over a second channel region, and through a first selected dielectric structure located between the first channel region and the second channel region.

In certain embodiments, the method includes forming bottom isolation features between adjacent channel regions, wherein interrupting designated gate lines with dielectric structures includes contacting the bottom isolation features with the dielectric structures.

In certain embodiments of the method, the channel regions include vertically-spaced nanosheets.

In another embodiment, a semiconductor device includes a first stack of spaced channel regions; a first metal gate surrounding the first stack of spaced channel regions; a second stack of spaced channel regions; a second metal gate surrounding the second stack of spaced channel regions; an intermediate dielectric structure located between the first metal gate and the second metal gate; and a conductive bridge extending across the intermediate dielectric structure and conductively interconnecting the first metal gate and the second metal gate.

In certain embodiments of the device, the first stack of spaced channel regions and the second stack of spaced channel regions each include a bottom channel region; and the device further includes a bottom isolation feature located between the respective bottom channel regions.

In certain embodiments of the device, the bottom isolation feature has an uppermost surface; the first metal gate contacts a first portion of the uppermost surface of the bottom isolation feature; and the second metal gate contacts a second portion of the uppermost surface of the bottom isolation feature.

In certain embodiments of the device, the intermediate dielectric structure contacts the bottom isolation feature between the first portion and the second portion of the uppermost surface of the bottom isolation feature.

In certain embodiments of the device, the first metal gate extends upward from the bottom isolation feature and terminates at a first uppermost surface; the second metal gate extends upward from the bottom isolation feature and terminates at a second uppermost surface; and the conductive bridge contacts the first metal gate at the first uppermost surface and contacts the second metal gate at the second uppermost surface.

In certain embodiments of the device, the intermediate dielectric structure has a first lateral width; and the conductive bridge has a second lateral width greater than the first lateral width.

In certain embodiments of the device, the first stack of spaced channel regions and the second stack of spaced channel regions are formed over a semiconductor substrate; each of the first stack of spaced channel regions and the second stack of spaced channel regions include an uppermost channel surface; the uppermost channel surfaces define an uppermost channel plane; and the uppermost channel plane is located between the conductive bridge and the semiconductor substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first channel region and a second channel region spaced apart from one another by a gap;
forming a metal gate line over the first channel region, over the second channel region and in the gap;
etching the metal gate line to define a first metal gate over the first channel region and a second metal gate over the second channel region, wherein the first metal gate and the second metal gate are disconnected; and
forming a conductive bridge in contact with the first metal gate and in contact with the second metal gate.

2. The method of claim 1, wherein:
the first channel region comprises first vertically-spaced nanostructures; and
the second channel region comprises second vertically-spaced nanostructures.

3. The method of claim 1, further comprising forming an intermediate dielectric structure between the first metal gate and the second metal gate.

4. The method of claim 3, further comprising etching the intermediate dielectric structure to form a recess, wherein the conductive bridge is formed in the recess.

5. The method of claim 3, further comprising forming a bottom isolation feature located between the first channel region and the second channel region, wherein forming the intermediate dielectric structure between the first metal gate and the second metal gate comprises forming the intermediate dielectric structure in contact with the bottom isolation feature.

6. The method of claim 3, wherein:
the first channel region and the second channel region are formed over a semiconductor substrate;
each of the first channel region and the second channel region include an uppermost channel surface;
the uppermost channel surfaces define an uppermost channel plane; and
the uppermost channel plane is located between the conductive bridge and the semiconductor substrate.

7. The method of claim 1, wherein etching the metal gate line to define the first metal gate over the first channel region and the second metal gate over the second channel region comprises:
forming an intermediate opening in the gap between the first channel region and the second channel region;
forming a first terminal opening adjacent the first channel region, wherein the first channel region is located between the first terminal opening and the intermediate opening; and
forming a second terminal opening adjacent the second channel region, wherein the second channel region is located between the second terminal opening and the intermediate opening.

8. The method of claim 7, further comprising:
forming an intermediate dielectric structure in the intermediate opening;
forming a first terminal dielectric structure in the first terminal opening;
forming a second terminal dielectric structure in the second terminal opening; and
etching the intermediate dielectric structure to form a recess, wherein the conductive bridge is formed in the recess.

9. A method comprising:
forming channel regions over a semiconductor substrate, wherein the channel regions extend in a first direction;
forming gate lines over the channel regions, wherein the gate lines extend in a second direction transverse to the first direction;
interrupting designated gate lines with dielectric structures; and
electrically reconnecting selected gates lines across selected dielectric structures.

10. The method of claim 9, wherein electrically reconnecting selected gates lines across selected dielectric structures comprises:
etching the selected dielectric structures to form recesses; and
forming conductive bridges in the recess.

11. The method of claim 9, wherein:
a first selected gate line terminates at a first non-selected dielectric structure and at a second non-selected dielectric structure; and
a conductive path of the first selected gate line extends from the first non-selected dielectric structure to the second non-selected dielectric structure over a first channel region, over a second channel region, and through a first selected dielectric structure located between the first channel region and the second channel region.

12. The method of claim 9, further comprising forming bottom isolation features between adjacent channel regions, wherein interrupting designated gate lines with dielectric structures comprises contacting the bottom isolation features with the dielectric structures.

13. The method of claim 9, wherein the channel regions comprise vertically-spaced nanosheets.

14. A semiconductor device, comprising:
a first stack of spaced channel regions;
a first metal gate surrounding the first stack of spaced channel regions;
a second stack of spaced channel regions;
a second metal gate surrounding the second stack of spaced channel regions;
an intermediate dielectric structure located between the first metal gate and the second metal gate; and
a conductive bridge extending across the intermediate dielectric structure and conductively interconnecting the first metal gate and the second metal gate.

15. The semiconductor device of claim 14, wherein:
the first stack of spaced channel regions and the second stack of spaced channel regions each include a bottom channel region; and
the device further comprises a bottom isolation feature located between the respective bottom channel regions.

16. The semiconductor device of claim 15, wherein:
the bottom isolation feature has an uppermost surface;
the first metal gate contacts a first portion of the uppermost surface of the bottom isolation feature; and
the second metal gate contacts a second portion of the uppermost surface of the bottom isolation feature.

17. The semiconductor device of claim 16, wherein the intermediate dielectric structure contacts the bottom isolation feature between the first portion and the second portion of the uppermost surface of the bottom isolation feature.

18. The semiconductor device of claim 17, wherein:
the first metal gate extends upward from the bottom isolation feature and terminates at a first gate uppermost surface;
the second metal gate extends upward from the bottom isolation feature and terminates at a second gate uppermost surface; and
the conductive bridge contacts the first metal gate at the first gate uppermost surface and contacts the second metal gate at the second gate uppermost surface.

19. The semiconductor device of claim 14, wherein:
the intermediate dielectric structure has a first lateral width; and
the conductive bridge has a second lateral width greater than the first lateral width.

20. The semiconductor device of claim 15, wherein:
the first stack of spaced channel regions and the second stack of-spaced channel regions are formed over a semiconductor substrate;
each of the first stack of spaced channel regions and the second stack of spaced channel regions include an uppermost channel surface;
the uppermost channel surfaces define an uppermost channel plane; and
the uppermost channel plane is located between the conductive bridge and the semiconductor substrate.
